(19) United States
(12) Patent Application Publication
(10) Pub. No.: US 2014/0308616 A1
(43) Pub. Date: Oct. 16, 2014

(54) COMPOSITION OF AN AQUEOUS ETCHANT CONTAINING A PRECURSOR OF OXIDANT AND PATTERNING METHOD FOR CONDUCTIVE CIRCUIT

(71) Applicant: Polychem UV/EB International Corp., Taipei City (TW)

(72) Inventors: Yung-Shu YANG, Taipei City (TW); Chun-Chieh HAN, Taipei City (TW)

(73) Assignee: Polychem UV/EB International Corp., Taipei City (TW)

(21) Appl. No.: 14/252,142

(22) Filed: Apr. 14, 2014

(30) Foreign Application Priority Data
Apr. 16, 2013 (TW) 102113430

(51) Int. Cl. H05K 3/06

(52) U.S. Cl. CPC H05K 3/067; H05K 3/06
USPC 430/297; 252/79.1; 216/13

(57) ABSTRACT

The present invention is primarily related to the composition of an aqueous etchant containing a precursor of oxidant and patterning methods for conductive circuits, in which the chemical structure of the precursor contains chlorine and can produce oxidants through various reactions. And, the patterned conductive circuits can be used for electronic devices, including printed electronics, sensors, displays, organic light emitting diodes (OLED), touch panels, electronic circuit boards, electrodes, electroluminescent (EL) films, antennas, and solar cells.

### BACKGROUND OF THE INVENTION

(a) Field of the Invention

The present invention relates to the composition of an aqueous etchant containing a precursor of oxidant, and a patterning method for conductive circuits.

b) Description of the Prior Art

The conventional etchants normally contain strong oxidants to directly carry out chemical etching of a conductive film to form the required patterning. However, disadvantages of such etchers include instability of the oxidants, difficult in controlling the quality, susceptibility to corrosion, or causing damage to production equipment.

Examples of the prior art, such as to use a high-energy charged particle beam to form a conductive pattern, or apply complicated photolithography manufacturing process. U.S. Pat. No. 7,704,677 B2 (Samsung Mobile Display Co, Ltd) discloses a method of applying a charged particle beam to irradiate a conductive polymer layer through a shadow mask. Non-conductive areas are formed on the irradiated areas of the conductive polymer layer, while conductive areas are formed by areas that are not irradiated with the charged particle beam. A very expensive charged particle beam accelerator is used to from the required conductive circuit. Another U.S. Pat. No. 8,252,386 B2 (Samsung Electronics Co., Ltd.) discloses a method of forming a conductive polymer film that mixes a photosensitive polymer resin with an oxidant. This mixture is then coated onto a transparent substrate, and a Vapor-Phase Polymerization (VPP) method is applied to form a conductive film on the surface of the transparent base material coated with the oxidant mixture. Then, UV (ultraviolet) light is applied to irradiate a photosensitive polymer containing photosensitive polyester acrylate or epoxy acrylate to form a conductive circuit. In addition, another U.S. Pat. No. 5,976,284 (Secretary of the Navy of the US, Geo-Centers, Inc.) discloses a method of using a photoresist being applied to form a masking layer using photolithography method on predetermined areas of the surface of a conductive polymer. A strong oxidant is further applied to increase the electrical resistance of the exposed conductive polymer portion, or to remove the portion of the exposed conductive polymer, and then removing the masking layer to form the patterned conductive polymer on the substrate. Yet another U.S. Pat. No. 6,340,496 (Agfa-Gevaert) discloses a printing solution containing direct oxidants, such as ClO⁻, BrO⁻, MnO₄⁻, Cr₂O7-, S₂O₈⁻ and H₂O₂, being applied to increase the electrical resistance of a conductive polymer on a substrate. The aforementioned prior arts use highly corrosive or oxidizing agents, involves expensive and complicated manufacturing processes to form a patterned conductive circuit. The present invention provides the advantages of high stability of the etchant, easy control over the degree of oxidation, much less corrosive to production equipment, low production equipment costs, reduce manufacturing steps, lower production costs and significantly higher production efficiency.

### SUMMARY OF THE INVENTION

The primary objective of the present invention is to provide an aqueous etchant containing a precursor of oxidant, wherein, the precursor contains chlorine, and after chemical decomposition, the precursor thereof produces at least one of the following oxidants: Cl⁻, ClO, H₂ClO₂, ClO₂, ClO₂⁻, ClO₃⁻, HClO₃ and HClO₄. The ph value of the aqueous etchant is greater than 7.0, and the precursor is a stabilized chlorine dioxide solution which contents less than 10% of the potential oxidant. The aqueous etchant is alkaline, containing carbonates, including at least either sodium carbonate or sodium bicarbonate. In addition, the aqueous etchant comprises either a water-soluble resin or a thickening agent. Furthermore, the water-soluble resin or the thickening agent may include one of the following compounds: polyvinyl alcohol (PVA), carboxymethylcellulose (CMC), polyvinylpyrrolidone (PVP), fumed silica. The oxidants are generated from the decomposition of the precursor by one of the following methods: radiation reaction, dehydration reaction, or thermal reaction, or a combination of more than one of the aforementioned methods. The patterning technology of the present invention can be used to pattern oxidized areas and form conductive circuit. A second objective of the present invention is to provide an electronic device containing a conductive substrate. The electronic device comprises a patterned conductive circuit produced by the aqueous etchant contains a precursor of oxidant. The conductive circuit is formed on the surface of a substrate, the conductive circuit contents conductive polymer or a transparent conductive metal oxide. The etchant layer containing the precursor of oxidant to cover specific areas predetermined for oxidation treatment on a conductive layer contents conjugated intrinsic conductive polymer, a transparent conductive metal oxide, or silver nanowires. Accordingly, an oxidation etching effect is produced on non-conductive areas that predetermined not required electric conductivity to form non-conductive areas. And, the remaining areas which are not covered with the precursor of oxidant form the required conductive circuit. The electric resistivity of the non-conductive areas formed is 100 times greater than the electric resistivity of the conductive circuit. The conductive layer comprises at least one of the following: ITO, ZnO, ZnOAl, or contains silver nanowires, or is a transparent conductive layer containing an conjugated conductive polymer, comprising at least one of the following compounds: PEDOT/PSS (poly (3,4-ethylenedioxythiophene) poly (styrenesulfonate)), Polyaniline (PANI), and Polypyrrole (PPy).

Another objective of the present invention is a method for patterning conductive circuits by using an aqueous etchant containing a precursor of oxidant to carry out patterning a conductive circuit on a conductive layer, comprising the follows:

Covering the surface of a substrate with a conductive layer containing a conductive polymer, wherein the substrate can be a plastic film such as a transparent PET (polyethylene terephthalate) film, PI (polyimide) film, plastic material; or an inorganic material such as glass, ceramics. Then covering areas predetermined that required to be oxidized on the surface of the conductive layer with a layer of etchant layer formed from the aforementioned aqueous etchant;

Applying one of the following methods: drying, heating, or irradiation, or a combination of more than one of the aforementioned methods, to cause the precursor of oxidant to produce an oxidant to oxidize the covered areas of conductive polymer to increase the electrical resistivity of the oxidized conductive layer, and achieve electrical resistivity more than 100 times of the original electrical resistivity, or to the extent of being completely non-conductive thereby forming non-conductive areas on the areas of the conductive layer predetermined not require conductivity, and the required conductive areas or conductive circuits are formed on remaining areas of non-oxidized conductive areas.

Furthermore, after the chemical reaction of the etchant, using water or an acidic aqueous solution with a pH (potential of hydrogen) value of less than 7, or an organic solvents to remove the aqueous etchant remaining on the surfaces of the non-conductive areas.

In addition, apart from the aforementioned etching method by radiation, another patterning method may be used. Firstly, the surface of the conductive layer is covered with a layer of the aqueous etchant layer. Then the etchant layer on the surfaces of the predetermined areas not requiring conductivity is irradiated by the radiation through the photo mask to form non-conductive areas. And, the areas not irradiated with radiation thereby forming the conductive circuit.

The wavelength of the aforementioned radiation includes any wavelength between 200˜800 nm (nanometer), causing the aqueous etchant layer being irradiated by the radiation to produce the oxidant to oxidize and etch the conductive layers predetermined not require conductivity to form high electrical resistivity or to the extent of non-conductive areas. And, the remaining areas of the conductive areas form the required conductive circuit on remaining areas. The electrical resistivity of the non-conductive areas is increased to be more than 100 times greater than the electrical resistivity of the conductive areas or to the extent of being completely non-conductive. Furthermore, water or an acidic aqueous solution with a pH value of less than 7, or an organic solvents used to remove the etchant left on the surface of the conductive and non-conductive areas.

The methods for coating the aqueous etchant on the conductive layer include one of the following methods: screen printing, transfer printing, gravure, letterpress, inkjet, dipping, spin coating, spray method, comma coating, wire bar coating, lithography, die coating, curtain coating, and roller coating.

Compared to the expensive, traditional yellow light development etching process, the present invention can significantly simplify the manufacturing processes, no need to use a photoresist and removing process for the photoresist, and further improving production efficiency, as well as reducing production costs.

To enable a further understanding of said objectives and the technological methods of the invention herein, a brief description of the drawings is provided below followed by a detailed description of the preferred embodiments.

### BRIEF DESCRIPTION OF THE DRAWINGS

FIG. 1 shows a schematic structural view of the present invention applied in an electronic device.

FIG. 2 shows a schematic view of an embodiment of the manufacturing method of the present invention.

FIG. 3 shows a schematic view of another embodiment of the manufacturing method of the present invention.

### DETAILED DESCRIPTION OF THE PREFERRED EMBODIMENTS

The present invention provides an aqueous etchant containing a precursor of oxidant. The chemical structure of the precursor of the oxidant contains chlorine. After the chemical decomposition, the precursor thereof produces at least one of the following oxidants: Cl⁻, ClO, H₂ClO₂, ClO₂, ClO₂⁻, ClO₃⁻, HClO₃ and HClO₄, wherein the aqueous etchant has a ph value greater than 7.0, preferably with a pH value of 8˜11. The amount of the potential oxidant within the precursor of oxidant is less than 10% of the total amount of the aqueous etchant, and the precursor is a stabilized chlorine dioxide solution. The aqueous etchant is alkaline and contains carbonates, including at least either sodium carbonate or sodium bicarbonate. In addition, the aqueous etchant can further contain either a water-soluble resin or a thickening agent. Furthermore, the water-soluble resin or the thickening agent comprises at least one of the following compounds: polyvinyl alcohol (PVA), carboxymethylcellulose (CMC), PVP (Polyvinylpyrrolidone), or fumed silica. The formation of the oxidants from the precursor includes one of the following methods: radiation reaction, dehydration reaction, or thermal reaction, or a combination of one or more of the aforementioned reactions. This etchant can be applied in the field of etching and patterning technologies for fabricating a conductive substrate 1, thereby forming a patterned conductive circuit.

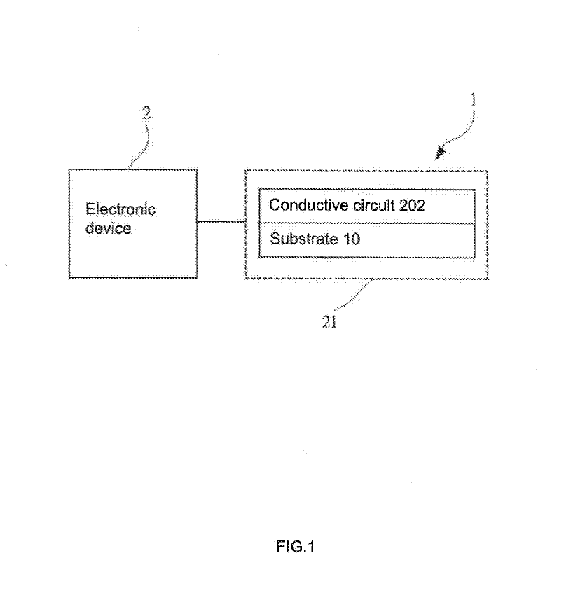

Referring to FIGS. 1, 2, and 3, the present invention comprises a base material 10, wherein the base material 10 can be a plastic film, such as a transparent PET (polyethylene terephthalate) film, a PI (polyimide) film, or an inorganic material such as glass, or ceramic; a conductive circuit 202 fabricated from either a transparent conductive polymer, a transparent conductive metallic oxide, or containing silver nanowires, which covers the surface of a base material 10.

A conductive layer 20 comprises a conjugated intrinsically conductive polymer which includes at least one of the following compounds: PEDOT/PSS (poly (3,4-ethylenedioxythiophene) poly (styrenesulfonate)), Polyaniline (PANI) and Polypyrrole (PPy). The surface of the conductive layer 20 is further covered with an etchant layer 30 of an aqueous etchant containing a precursor of oxidant, wherein the chemical structure of the precursor contains chlorine. After the chemical decomposition of the precursor, thereof the precursor produces at least one of the following oxidants: Cl⁻, ClO, H₂ClO₂, ClO₂, ClO₂⁻, ClO₃⁻, HClO₃ and HClO₄.

The etchant layer 30 covers the predetermined areas of the conductive layer 20 which comprises a conductive polymer having conjugated intrinsic conductivity, and the predetermined areas are the areas to be oxidizied and form non-conductive areas 201, and the patterned conductive circuit 202 is formed on remaining areas excluding the non-conductive areas 201, forms the conductive substrate 1. The electrical resistivity of the predetermined non-conductive areas 201 has resistivity which is more than 100 times greater than the electrical resistivity of the conductive areas (i.e. the conductive circuit 202) or to the extent of being completely non-conductive.

Referring to FIG. 1, the conductive substrate 1 can be applied in an electronic device 2 provided with a sensor 21 function and electrically connected to the conductive substrate 1 which is formed by the aqueous etchant containing a precursor of oxidant. In addition, the conductive substrate 1 can also be applied in electronic devices, including printed electronics, sensors, displays, organic light emitting diodes (OLED), touch panels, electronic circuit boards, electrodes, electroluminescent (EL) films, antennas, and solar cells, etc.

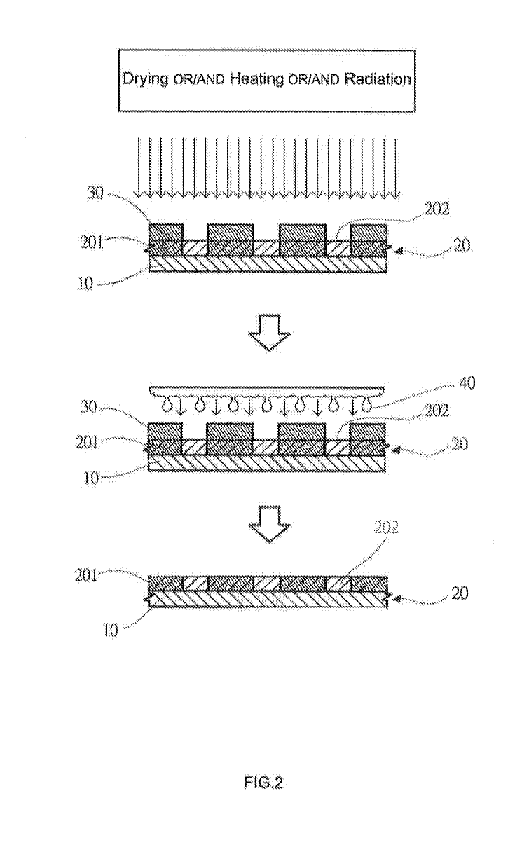

Referring to FIG. 2, which shows a first embodiment of a manufacturing method of the present invention which is to use the aqueous etchant, contains a precursor of oxidant which chemical structure contents chlorine to carry out patterning conductive circuit on a conductive layer 20, the manufacturing method comprises the following:

Covering the surface of the base material 10 with the conductive layer 20 that contains a conjugated conductive polymer with intrinsic conductivity;

Covering the predetermined areas on the surface of the conductive layer 20 predetermined for oxidation treatment with a layer of the etchant layer 30 formed from the aqueous etchant;

Applying one of the following methods: drying, heating, or radiation, or a combination of more than one of the aforementioned methods, to cause the precursor of oxidant to produce an oxidant which oxidize and increase the electrical resistivity of the contacted conductive layer 20. The electric resistivity of the oxidized areas has the value of the original electrical resistivity by more than 100 times or to the extent of being completely non-conductive, thereby forming the non-conductive areas 201 on the areas of the conductive layer 20 predetermined not require conductivity, and further forming the required conductive circuit 202 on remaining areas excluding the non-conductive areas 201; and

Finally, applying a cleaning solution 40 selected from one of the following: water, an acidic aqueous solution with a pH (potential of hydrogen) value of less than 7, or an organic solvent, to remove the etchant on the surface of the conductive layer 20.

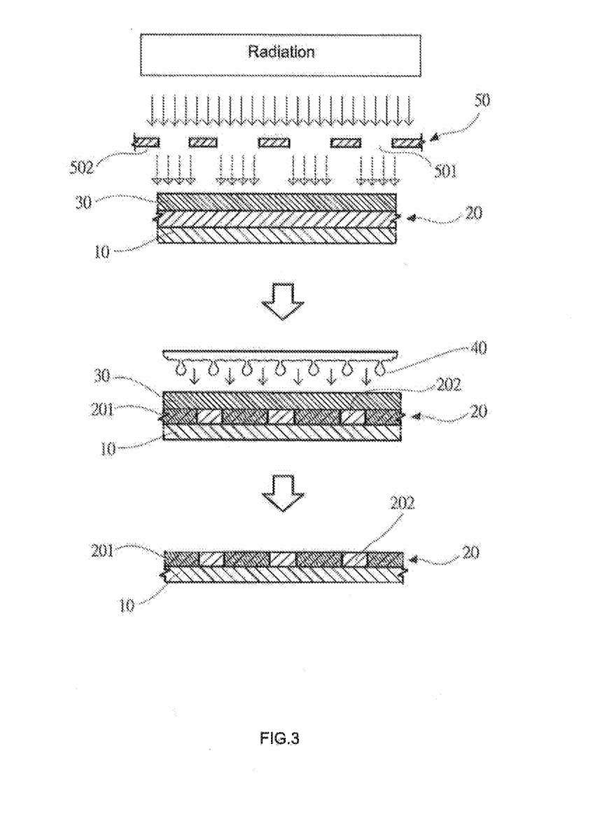

Referring to FIG. 3, in addition to the aforementioned method which applying radiation causing the precursor of oxidant to produce a oxidant to oxidize the contacted conductive layer 20 to carry out an etching and patterning method, the radiation can be further carried out through a photo mask 50, which is applied for preset patterning of transparent areas 501 predetermined for oxidation and non-transparent areas 502 predetermined not require oxidation, thereby achieving radiation on predetermined areas of the etchant layer 30 through the transparent areas 501 of the photo mask 50, and causing the precursor of the oxidant of the etchant layer 30 irradiated by radiation to produce a oxidant, such that the contacted conductive layer 20 is oxidized by the oxidant to carry out etching thereof to form the non-conductive areas 201, while the areas not irradiated with the radiation are masked by non-transparent areas 502 to form the conductive circuit 202. The wavelength of the aforementioned radiation includes any wavelength between 200˜800 nm (nanometer).

The aforementioned methods for coating and printing the aqueous etchant on the conductive layer include one of the following methods: screen printing, transfer printing, gravure, letterpress, inkjet, dipping, spin coating, spray method, comma coating, wire bar coating, lithography, die coating, curtain coating, and roller coating.

As described above, one of the embodiments of the present invention, the chemical composition of an aqueous etchant containing a precursor of oxidant, wherein the etchant is alkaline and contains carbonates, and comprises at least one of the following: sodium carbonate and sodium bicarbonate. For example, 20 g of 5% aqueous stabilized chlorine dioxide, added to 80 g of water-soluble resin with solid content of 10˜30%, such as polyvinyl alcohol (PVA), polyvinylpyrrolidone (PVP) or 0.3˜5% of a thickening agent such as, carboxymethylcellulose (CMC), fumed silica, and the like, to adjust the viscosity of the etchant to fit different printing methods. In addition, if low viscosity for the etchant is required for certain printing methods, such as spin coating method or inkjet printing method, then the amount of water-soluble resin, thickening agent, fumed silica, and the like, can be reduced, or not added at all. Furthermore, approximately 0.2˜5% of wetting agent, defoamer, thixotropic agent, or leveling agent and so on, can also be added to the etchant to improve printing and coating quality. The conductive substrate 1 formed by the aforementioned etchant and manufacturing method can be used in various electronic devices, such as the electronic device provided with a sensor 21 shown in FIG. 1.

A second embodiment of the present invention is applied in a manufacturing method using the aqueous etchant containing a precursor of oxidant, wherein the etchant is alkaline containing carbonates, which comprise at least either sodium carbonate or sodium bicarbonate. The second embodiment comprises the printing of the alkaline etchant containing a chlorine dioxide precursor. The printing methods for the etchant for example, include using screen printing method to print the etchant to cover the areas predetermined not require conductivity on the surface of the a PEDOT/PSS transparent conductive polymer film (original electrical resistivity is 90 ohm/sq). Then, use air drying (a dehydration reaction, Dry-Phase) method or heating method, or a combination of more than one of the aforementioned methods to cause the chlorine dioxide precursor to produce a strong oxidant, including at least one of the following: Cl⁻, ClO, H₂ClO₂, ClO₂, ClO₂⁻, ClO₃⁻, HClO₃ and HClO₄, to oxidize the areas requiring oxidation in contact with the etchant to form the non-conductive areas 201, thus significantly reduces the electrical conductivity of the transparent conductive polymer film of these areas, and substantially increasing the electric resistivity by ten million or to above one hundred million times, to approximately more than 10×E+9˜+10 ohm/sq., or even to the extent of being completely non-conductive. And, the conductive coating on the predetermined areas not covered with the etchant forms the conductive circuit 202. Furthermore, a cleaning solution 40, such as water, or an acidic solution with a pH (potential of hydrogen) of less than 7.0, or an organic solvent, can be further applied to remove the etchant on the surfaces of the non-conductive areas 201.

A third embodiment of the present invention is a method for patterning conductive circuit. It uses radiation and the aqueous etchant containing a precursor of strong oxidant, and a photo mask which is disposed above a conductive layer. Firstly, the surface of the conductive layer is covered with a layer of aqueous etchant covering an area greater than the irradiation area. The aqueous etchant is alkaline and contains a precursor of oxidant, which contains chlorine. The precursor can be a precursor of chlorine dioxide. Using spin coating method to cover the surface of a PEDOT/PSS transparent conductive polymer film (original electrical resistivity is 90 ohm/sq.) with the etchant. Then, using radiation to irradiate the etchant through the photo mask 50 to cause radiation passing through the transparent areas 501 of the photo mask 50 to irradiate the chlorine dioxide precursor of the etchant to produce at least one oxidant from the following: Cl⁻, ClO, H₂ClO₂, ClO₂, ClO₂⁻, ClO₃⁻, HClO₃ and HClO₄, thereby causing oxidation of the predetermined areas in contact with the etchant to form the non-conductive areas 201. The electrical conductivity of the conductive polymer of these areas is significantly lowered, and the electric resistivity is substantially increased by ten million times to more than one hundred million times, reaching an approximate value of more than 10×E+9˜+10 ohm/sq., or to the extent of being completely non-conductive. And, the areas which are not irradiated by the radiation thus form the conductive circuit 202. Furthermore, a cleaning solution 40, including one of the following: water, or an acidic solution with a pH (potential of hydrogen) of less than 7.0, or an organic solvent, can be further used to remove the unreacted and the reacted etchant layer 30 on the surface of the base material 10. Compared to the expensive, traditional photolithgraphy etching method, the present invention significantly reduces the needs for some materials and processes, such as the use of photoresist, developing solution and the process to remove the photoresist to etc; therefore further increasing production efficiency and reducing production costs. It is of course to be understood that the embodiments described herein are merely illustrative of the principles of the invention and that a wide variety of modifications thereto may be achieved by persons skilled in the art without departing from the spirit and scope of the invention as set forth in the following claims.

What is claimed is:

1. A aqueous etchant contains a precursor of oxidant for patterning conductive circuit, wherein the chemical structure of the precursor contains chlorine, and the precursor produces at least one of the following oxidants: Cl⁻, ClO, H₂ClO₂, ClO₂, ClO₂⁻, ClO₃⁻, HClO₃ and HClO₄.

2. A manufacturing method using an aqueous etchant containing a precursor of oxidant for patterning conductive circuit on a conductive layer, comprising steps of:
a) covering the surface of a substrate with conjugated transparent conductive polymer;
b) covering the areas of the conductive layer predetermined for oxidation treatment on the conductive substrate with an aqueous etchant containing a precursor of oxidant, wherein the chemical structure of the precursor contains chlorine, and the precursor produces at least one of the following oxidants: Cl⁻, ClO, H₂ClO₂, ClO₂, ClO₂⁻, ClO₃⁻, HClO₃ and HClO₄; and
c) using one or more than one of the following methods: drying, heating, radiation, to cause the precursor to produce the a oxidant, whereby etching is carried out on areas of the conductive layer predetermined not require conductivity to form non-conductive areas, and the rest of the conductive layer excluding the non-conductive areas thereby forming the conductive circuit; wherein electrical resistivity of the non-conductive areas is 100 times greater than the electrical resistivity of the conductive circuit to the extent of being completely non-conductive.

3. A manufacturing method using an aqueous etchant containing a precursor of oxidant for patterning conductive circuit on a conductive layer, comprising steps of:
a) covering the surface of a substrate with a transparent conducting layer containing an intrinsically conductive conjugated conductive polymer;
b) covering the surface of the conductive layer with a layer of aqueous etchant containing a precursor of oxidant, wherein the chemical structure of the precursor contains chlorine, and the precursor produces at least one of the following oxidant: Cl⁻, ClO, H₂ClO₂, ClO₂, ClO₂⁻,ClO₃⁻, HClO₃ and HClO₄⁻;
c) placing a photo mask above the conductive layer and irradiating the areas predetermined not require conductivity through the photo mask; the irradiated etchant on the conductive layer produces the oxidant, whereby etching is carried out on the areas of the conductive layer predetermined not require conductivity to form the non-conductive areas of high electrical resistivity or completely non-conducting areas thereby the remaining areas excluding the non-conductive areas form the required conductive circuit; wherein the electrical resistivity of the non-conductive areas is 100 times greater than the electrical resistivity of the conductive circuit to the extent of being completely non-conductive; and
d) using one of the following cleaning solutions: water, acidic aqueous solution with a pH (potential of hydrogen) value of less than 7, organic solvent, to remove the etchant.

4. The aqueous etchant containing a precursor of oxidant according to claim 1, wherein the oxidant is produced by using one or more than one of the following methods: radiation reaction, dehydration reaction, and thermal reaction.

5. The manufacturing method using an aqueous etchant containing a precursor of oxidant for patterning conductive circuit on a conductive layer according to claim 2, wherein, after forming the required conductive circuit on the surface of the conductive layer, one of the following cleaning solutions: water, an acidic aqueous solution with a pH value of less than 7, or an organic solvent, is used to remove the etchant.

6. The aqueous etchant containing a precursor of oxidant, according to claim 1, wherein the precursor is a stabilized chlorine dioxide solution.

7. The manufacturing method using aqueous etchant containing a precursor of oxidant on a conductive layer, according to claim 2, wherein the precursor is a stabilized chlorine dioxide solution.

8. The manufacturing method using aqueous etchant containing a precursor of oxidant on a conductive layer, according to claim 3, wherein the precursor is a stabilized chlorine dioxide solution.

9. The aqueous etchant containing a precursor of oxidant, according to claim 1, wherein the aqueous etchant is alkaline with a pH value greater than 7.0.

10. The manufacturing method using aqueous etchant containing a precursor of oxidant on a conductive layer, according to claim 2, wherein the aqueous etchant is alkaline with a pH value greater than 7.0.

11. The manufacturing method using aqueous etchant containing a precursor of oxidant on a conductive layer according to claim 3, wherein the aqueous etchant is alkaline with a pH value greater than 7.0.

12. The aqueous etchant containing a precursor of oxidant, according to claim 6, wherein the aqueous etchant contains carbonates, including at least either sodium carbonate or sodium bicarbonate.

13. The manufacturing method using aqueous etchant containing a precursor of oxidant on a conductive layer according to claim 7, wherein the aqueous etchant contains carbonates, including at least one of the following: sodium carbonate or sodium bicarbonate.

14. The manufacturing method using aqueous etchant containing a precursor of oxidant on a conductive layer according to claim 8, wherein the aqueous etchant contains carbonates, including at least one of the following: sodium carbonate or sodium bicarbonate,

15. The aqueous etchant containing a precursor of oxidant, according to claim 1, wherein the aqueous etchant contains either a water-soluble resin or a thickening agent, and the water-soluble resin or the thickening agent including at least one of the following compounds: polyvinyl alcohol (PVA), carboxymethylcellulose (CMC), polyvinylpyrrolidone (PVP), or fumed silica.

16. The manufacturing method using aqueous etchant containing a precursor of oxidant on a conductive layer, according to claim 2, wherein the aqueous etchant contains either a water-soluble resin or the thickening agent, and the water-soluble resin or the thickening agent including at least one of the following compounds: polyvinyl alcohol (PVA), carboxymethylcellulose (CMC), polyvinylpyrrolidone (PVP) or fumed silica.

17. The manufacturing method using aqueous etchant containing a precursor of oxidant on a conductive layer, according to claim 3, wherein the aqueous etchant contains either a water-soluble resin or the thickening agent, and the water-soluble resin or the a agent, including at least one of the following compounds: polyvinyl alcohol (PVA), carboxymethylcellulose (CMC), polyvinylpyrrolidone (PVP) or fumed silica.

18. The manufacturing method using an aqueous etchant containing a precursor of oxidant for patterning conductive circuit on a conductive layer, according to claim 2, the conductive layer is a transparent conducting layer comprising silver nanowires.

19. The manufacturing method using an aqueous etchant containing a precursor of oxidant for patterning conductive circuit on a conductive layer, according to claim 3, the conductive layer is a transparent conducting layer comprising silver nanowires.

20. The aqueous etchant contains a precursor of oxidant for patterning the conductive circuit according to claim 1, wherein the conductive circuit contains an intrinsically conductive conjugated polymer, including PEDOT/PSS (poly (3,4-ethylenedioxythiophene) poly (styrenesulfonate)), Polyaniline (PANI) and Polypyrrole (PPy).

21. The manufacturing method using aqueous etchant containing a precursor of oxidant on a conductive layer according to claim 2, wherein the conductive circuit contains an intrinsically conjugated conductive polymer, including: PEDOT/PSS (poly (3,4-ethylenedioxythiophene) poly (styrenesulfonate)), Polyaniline (PANI) and Polypyrrole (PPy).

22. The manufacturing method using aqueous etchant containing a precursor of oxidant on a conductive layer according to claim 3, wherein the conductive circuit contains an intrinsically conjugated conductive polymer, including: PEDOT/PSS (poly (3,4-ethylenedioxythiophene) poly (styrenesulfonate)), Polyaniline (PANI) and Polypyrrole (PPy).
